(19) United States
(12) Patent Application Publication
(10) Pub. No.: US 2008/0296778 A1
(43) Pub. Date: Dec. 4, 2008

(54) Interconnection Structure and Integrated Circuit

(75) Inventors: Martin Roessiger, Dresden (DE); Christoph Kleint, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/755,483

(22) Filed: May 30, 2007

(51) Int. Cl. H01L 23/52; H01L 21/3205

(52) U.S. Cl. 257/774; 438/640; 257/E23.141; 257/E21.294

(57) ABSTRACT

A method of manufacturing an integrated circuit and an interconnection structure includes forming a conductive portion along a first direction and conductive lines along a second direction.

### BACKGROUND

Interconnection structures are widely used in semiconductor integrated circuits to connect semiconductor devices or circuit parts to each other or to external pads. Memory cells of memory arrays such as volatile or non-volatile memory arrays use interconnection structures to connect the memory cells of the array to support circuits such as sense amplifiers or decoders, for example. Future technologies aim for smaller minimum feature sizes to increase the storage density and to reduce the cost of semiconductor chips. When scaling semiconductor devices of integrated circuits to smaller minimum feature sizes, interconnection structures also have to be scaled down. Scaling of interconnection structures such as bitlines and bitline contacts to smaller minimum feature sizes is crucial and challenging in view of feasibility of lithography, taper of contact plugs, contact fills and short circuits between neighboring contact plugs, for example.

### BRIEF DESCRIPTION OF THE DRAWINGS

Features and advantages of embodiments of the invention will be apparent from the following detailed description. The drawings are not necessarily to scale. Emphasis is placed up on illustrating the principles. Like reference numerals refer to like elements throughout the drawings.

FIGS. 1A-4C show plan views and cross-sectional views of a section of a carrier during manufacture of an interconnection structure according to an embodiment of the invention;

FIGS. 5A to 7C show plan views and cross-sectional views of a section of a carrier during manufacture of an interconnection structure according to a further embodiment of the invention;

FIGS. 8A to 13C show plan views and cross-sectional views of a section of a carrier during manufacture of an interconnection structure according to yet another embodiment of the invention; and

FIGS. 14 to 16 show flow charts illustrating embodiments of methods for manufacturing an interconnection structure;

FIG. 17 is a schematic illustration of an integrated circuit according to a further embodiment; and

FIG. 18 is a simplified view of an electronic system according to a further embodiment.

### DETAILED DESCRIPTION

In the following detailed description reference is made to the accompanying drawings, which form a part thereof and in which specific embodiments are shown by way of illustration. In this regard, directional terminology such as “top,” “bottom,” “front,” “back,” etc., is used with reference to the orientation of the figures being described. Since components of embodiments may be positioned in a number of different orientations, the directional terminology is used for purposes of illustration only and in no way limiting. It is to be understood that further embodiments may be utilized and structural or logical changes may be made. The following detailed description thereof is not to be taken in a limiting sense.

According to an embodiment, a method of manufacturing an integrated circuit comprises forming a structure on a carrier, the structure comprising at least a conductive portion, etching recesses into the conductive portion to segment the conductive portion into a plurality of conductive regions arranged along a first direction, filling the recesses with a dielectric material and forming conductive lines above the conductive regions, wherein each of the conductive lines is electrically coupled to at least one of the conductive regions and extends along a second direction intersecting the first direction.

As an example, the conductive lines and conductive regions may form bitlines and bitline contacts connecting memory cells to support circuits. However, the conductive lines and conductive regions may also be used to connect any circuit part, e.g., a functional region of an integrated circuit to a further circuit part. The conductive lines and conductive regions may be formed of any conductive material such as metal, noble metal, metal alloys or doped semiconductors. Although a common material may be used to realize the conductive lines and the conductive regions, material compositions of these parts may also entirely or partly differ from each other. Exemplary materials include W, Ti, Wn, TaN, Cu, Ta, Al, metal suicides, doped silicon of any crystal structure such as doped polysilicon or doped amorphous silicon, or any combination thereof. The conductive lines and the conductive regions may further comprise a liner, for example.

The carrier may comprise a semiconductor substrate such as a silicon substrate, which may be pre-processed in any way. As a further example the carrier may be a SOI (silicon-on-insulator) carrier. Hence, the carrier may already include semiconductor zones formed therein in order to provide semiconductor devices. Furthermore, the carrier may also comprise any kind of insulating or conductive structure formed thereon before the structure is provided. In case of a non-volatile memory, the carrier may be pre-processed in such a way that source and drain regions as well as gate dielectrics and gate electrodes are already provided before provision of the structure on the pre-processed carrier.

It is further to be noted that etching the conductive portion to achieve separate conductive regions may not only lead to a chain of consecutive conductive regions arranged along the first direction but also to a plurality of parallel chains, each of the chains comprising conductive regions consecutively arranged along the first direction. Hence, the conductive portion may be etched to provide a plurality of bitline contact chains in a flash NAND memory, for example.

The structure may comprise a conductive and an insulating portion. Such a structure may be provided by first etching an opening into an insulating layer followed by filling the opening with a conductive material to provide the conductive portion laterally adjacent to the remaining insulating layer constituting the insulating portion.

The conductive portion may constitute the structure. Thus, the structure may be made up only of the conductive portion. Hence, the recesses etched into the conductive portion remove those material parts of the conductive portion that are not to be used as conductive regions. As an example, a major part of the conductive portion may be removed by etching recesses therein to achieve one or even more chains of conductive regions along the first direction.

The conductive portion may comprise a liner layer and a metal layer formed thereon. As an example, the liner layer may comprise Ti/TiN and the metal layer may be of W. However, any kind of liner layer and metal layer appropriately chosen to achieve a desired resistance with regard to the contact to be formed may be utilized.

According to a further embodiment, the conductive portion comprises a doped semiconductor layer. As an example, the doped semiconductor layer may be of doped polysilicon. Again, any kind of doped semiconductor layer may be chosen which allows to achieve an interconnection structure comprising desired properties, e.g., with regard to conductivity or process integration.

According to a further embodiment, the opening and recesses are formed by tapered etch processes such that a dimension of a bottom side of the conductive regions is larger along the first direction and smaller along the second direction than the corresponding dimensions of the top side of the conductive regions, respectively. Taking into account a taper caused by an etch process starting from the top side to the bottom side, opposite slopes of sidewall profiles of the conductive regions are introduced if sidewalls opposite along the first direction are determined by a taper of an etch process affecting the conductive portion and sidewalls opposite along the second direction are determined by a taper of an etch process affecting the insulating layer.

The recesses may also be formed by a tapered etch process such that the dimensions of the conductive regions along the first and second directions are larger at a bottom side than at a top side. Here, the recesses etched into the conductive portion surround each of the conductive regions such that a taper of sidewalls opposed along the first direction is similar or equal to a taper of sidewalls opposed along the second direction. Hence, the conductive regions may be shaped from the conductive portion in a single patterning step, e.g., a single etch process.

A bottom side of each of the conductive regions may adjoin to a top side of a conductive zone. The conductive zone may be a semiconductor zone of an active area of a semiconductor device, for example. As an example, the conductive regions may serve as bitline contacts contacting an active area assigned to a string of NAND flash memory cells. Although the conductive zones may be active areas of any kind of semiconductor device, these zones may also be part of a metal layer such as a metal line.

The conductive regions may be shaped as contact plugs.

A further embodiment relates to a method of manufacturing an integrated circuit comprising etching a linear opening into an insulating layer formed on a carrier, the linear opening extending along a first direction, filling the linear opening with a conductive structure, etching recesses into the conductive structure to segment the conductive structure into a plurality of conductive regions arranged along the first direction, filling the recesses with a dielectric material and forming conductive lines above the insulating layer and the conductive regions, wherein each of the conductive lines is electrically coupled to at least one of the conductive regions and extends along a second direction intersecting the first direction.

The linear opening and recesses may be formed by tapered etch processes such that a dimension of a bottom side of the conductive regions is larger along the first direction and smaller along the second direction than the corresponding dimensions of the top side of the conductive regions, respectively. It is to be noted that the term “linear opening” used herein refers to an opening that extends along a specified direction. However the opening may extend along the specified direction not only as a linear line but also as a undulated line or it may comprise any other kind of modulation.

According to a further embodiment, prior to etching the recesses into the conductive structure, an etch mask structure comprising parallel lines is formed on the insulating layer and the conductive structure, wherein the parallel lines are equally spaced along the first direction and extend along the second direction. The conductive regions to be formed are delimited along the second direction by the insulating layer and their arrangement along the first direction may be defined by the coverage provided by the etch mask structure. An etch process allows for a segmentation of the conductive structure along the first direction by selective removal of those parts of the conductive structure which are not covered by the etch mask structure.

A pitch between two neighboring conductive lines may equal 2×F, wherein F denotes a minimum lithographic feature size.

A further embodiment relates to a method of manufacturing an interconnection structure comprising forming a conductive structure on a carrier, etching recesses into the conductive structure to segment the conductive structure into a plurality of conductive regions arranged along a first direction, filling the recesses with a dielectric material and forming conductive lines above the conductive regions and the dielectric material, wherein each of the conductive lines is electrically coupled to at least one of the conductive regions and extends along a second direction intersecting the first direction. Here, the recesses etched into the conductive structure surround each of the conductive regions. Hence, a profile of sidewalls opposed along the first direction is similar or equal to a profile of sidewalls opposed along the second direction. The patterning of the conductive structure resulting in the conductive regions may thus be carried out by a single patterning step, e.g., a single etch process.

According to a further embodiment, an integrated circuit comprises contact plugs of a doped semiconductor material consecutively arranged along a first direction and conductive lines extending along a second direction intersecting the first direction, wherein a top side of each of the contact plugs is in contact with one of the conductive lines and opposing sidewalls delimiting the contact plugs along the first direction are tapered from a bottom side to the top side. Hence, a dimension of the contact plugs along the first direction is larger at the bottom side than at the top side.

A bottom side of each of the contact plugs may be in contact with a top side of a conductive zone.

A further embodiment relates to an integrated circuit, wherein opposing sidewalls delimiting the contact plugs along the second direction are tapered from the top side to the bottom side.

An integrated circuit according to a further embodiment comprises contact plugs consecutively arranged along a first direction and conductive lines extending along a second direction intersecting the first direction, wherein a top side of each of the contact plugs is in contact with one of the conductive lines, opposing sidewalls delimiting the contact plugs along the first direction are tapered from a bottom side to the top side and the contact plugs further comprise a liner being present at the bottom side as well as at opposing sidewalls delimiting the contact plugs along the second direction but absent at opposing sidewalls delimiting the contact plugs along the first direction.

A further embodiment relates to an integrated circuit comprising contact plugs including a liner being present at a bottom side but absent at sidewalls thereof, the contact plugs being consecutively arranged along a first direction, conductive lines extending along a second direction intersecting the first direction, wherein a top side of each of the contact plugs is in contact with one of the conductive lines, and opposing sidewalls delimiting the contact plugs along the first direction are tapered from a bottom side to the top side.

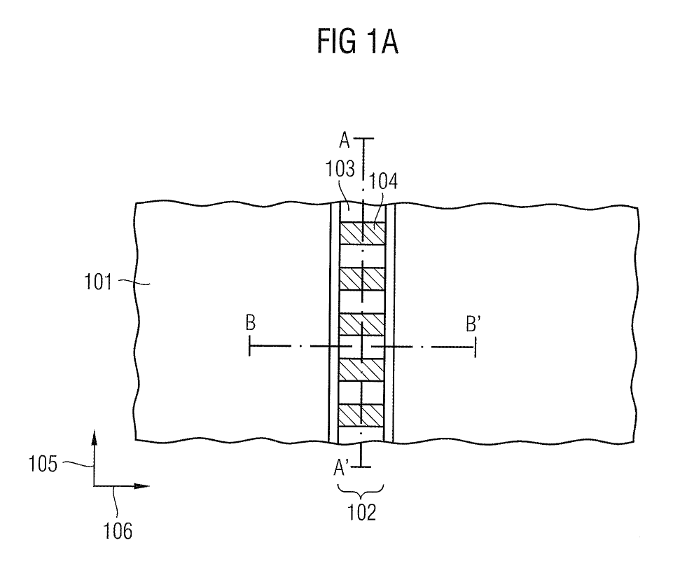

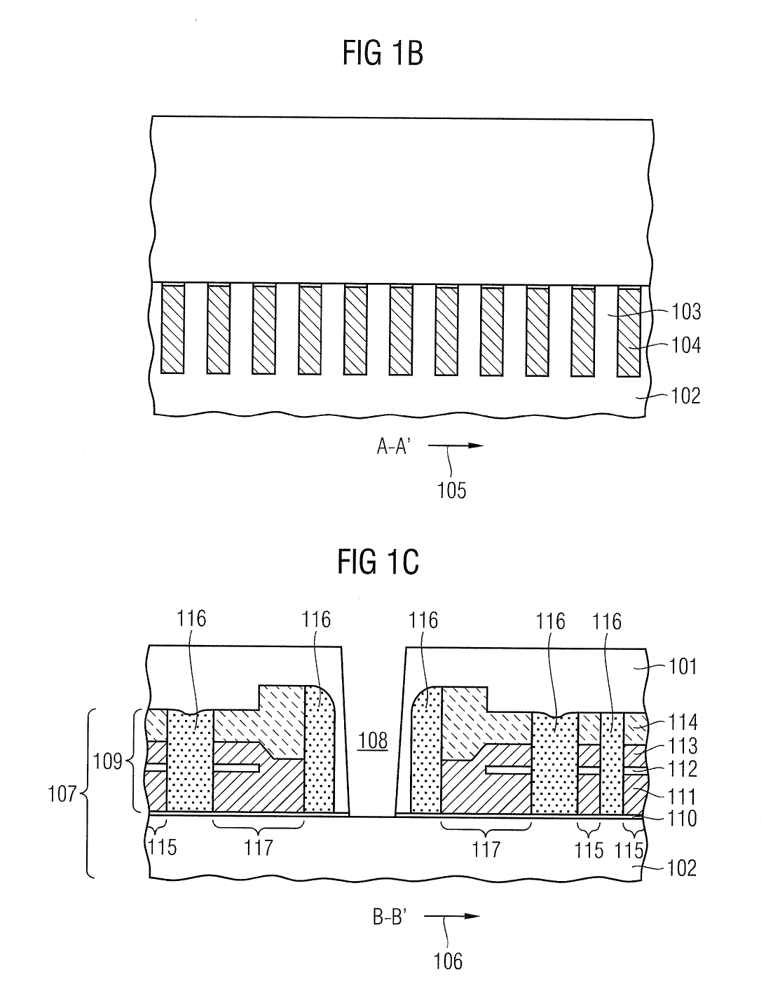

FIGS. 1A to 4C refer to a method of manufacturing an interconnection structure according to an exemplary embodiment. As an example, the features of this embodiment are exemplified with regard to an interconnection structure used to provide bitline contacts and bitlines in a NAND flash memory.

Referring to the schematic top view of FIG. 1A, there is provided an insulating layer 101 comprising a linear opening exposing part of a top side of a semiconductor substrate 102. The exposed part of the semiconductor substrate includes alternately arranged regions of active areas 103 and trench isolations 104 along a first direction 105 being perpendicular to a second direction 106.

Referring to the schematic cross-sectional view in FIG. 1B, which is taken along the first direction 105 and denoted by an intersection line A-A′ in FIG. 1A, the trench isolations 104 extend into the semiconductor substrate 102 and provide an electric isolation of neighboring active areas 103. The trench isolations 104 may comprise any kind of insulating material. As an example, silicon oxide may be used.

Referring to the schematic cross-sectional view illustrated in FIG. 1C, which is taken along the second direction 106 and denoted by an intersection line B-B′ in FIG. 1A, a pre-processed carrier 107 comprising the semiconductor substrate 102 is illustrated. The insulating layer 101 comprising the linear opening 108 is formed on the pre-processed carrier 107. Apart from the semiconductor substrate 102, the pre-processed carrier 107 also comprises a gate arrangement 109 of a floating gate flash NAND string. It is to be noted that the carrier 107 may be pre-processed in any way and is not restricted to the specific arrangement of FIG. 1C. On top of the semiconductor substrate 102, there is provided a dielectric tunnel layer 110. As an example, the dielectric tunnel layer 110 may be of silicon oxide. On the dielectric tunnel layer 110 there is provided a floating gate 111 for charge storage. An interdielectric layer 112 such as an ONO (Oxide-Nitride-Oxide) layer isolates the floating gate 111 from a control gate 113 arranged on top of the interdielectric layer 112. As an example, the floating gate 111 and the control gate 113 may be formed of doped polysilicon (polycrystalline silicon). A cap structure 114 is provided on the control gate 113. The floating gate 111 and the control gate 113 of neighboring NAND memory cells 115 are isolated from each other by isolation regions 116. In the region of a selection transistor 117, the floating gate 111 and the control gate 113 are brought together. For reasons of convenience and clarity, semiconductor zones formed within the semiconductor substrate 102 are not illustrated in the simplified cross-sectional views.

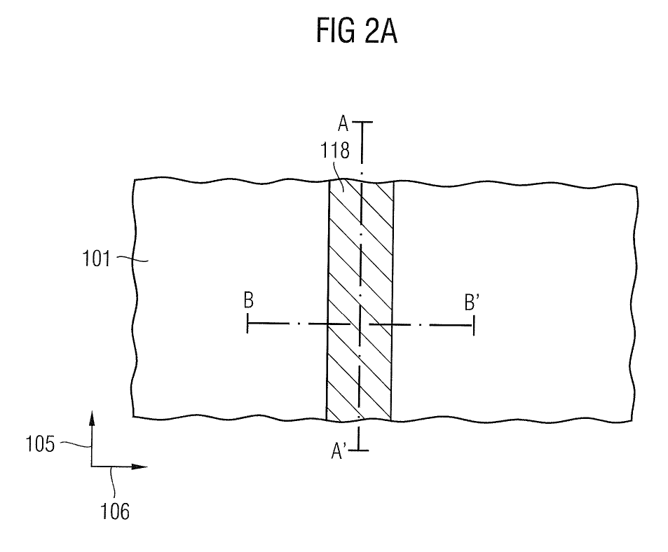

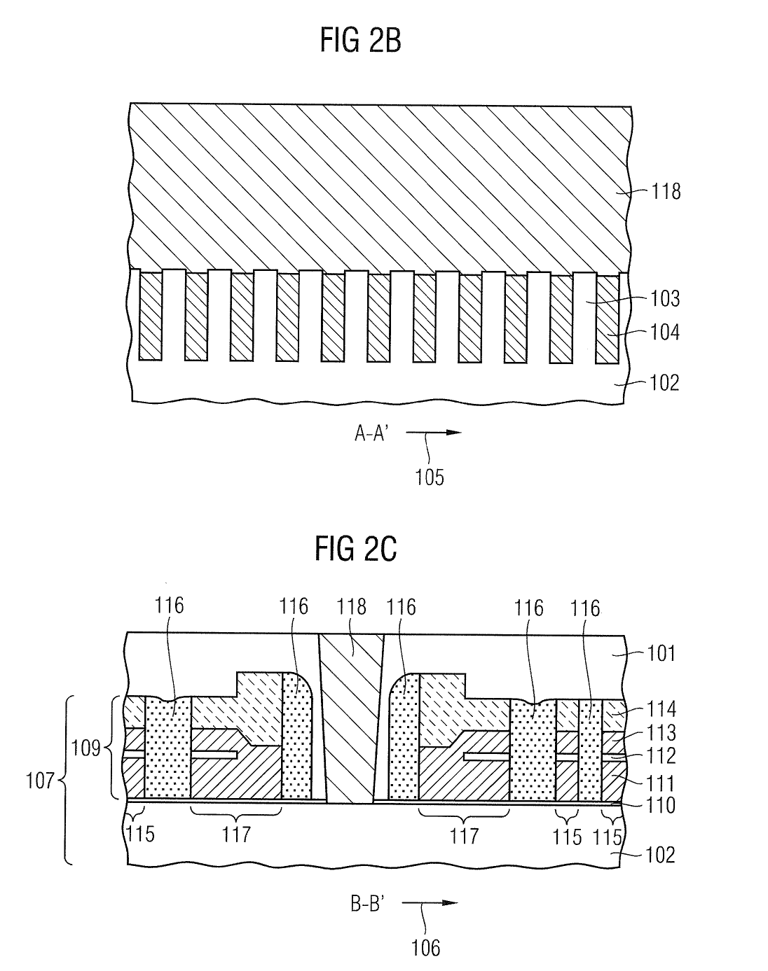

Referring to the schematic top view in FIG. 2A and following the process stage shown in FIG. 1A, a conductive structure 118 is filled into the linear opening 108 of the insulating layer 101.

Schematic cross-sectional views with regard to the intersection lines denoted by A-A′ and B-B′ in FIG. 2A are shown in FIGS. 2B and 2C, respectively. A material of the conductive structure 118 may first be deposited in such a way that it not only fills the linear openings 108 but also covers a top side of the insulating layer 101. Thereafter, this material may be removed from the top side of the insulating layer 101 and remains within the linear opening as the conductive structure 118. Removal of the material may be achieved by chemical-mechanical polishing, for example. As an example, the conductive structure may be formed of doped polysilicon.

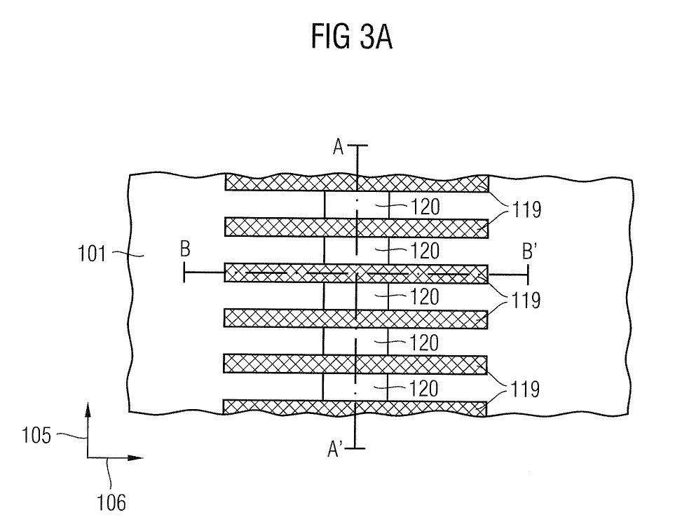

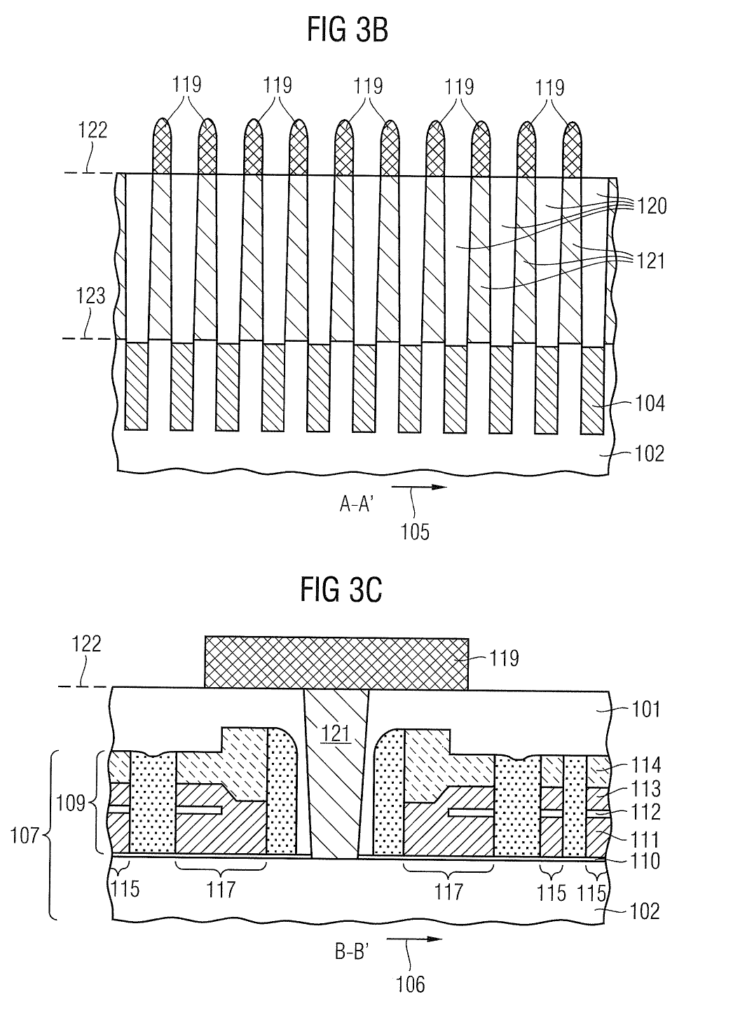

Referring to the schematic top view of FIG. 3A, an etch mask structure comprising equally spaced parallel lines running along the second direction 106 is provided on the insulating layer 101 and the conductive structure 118. Uncovered parts of the conductive structure 118 are etched to provide recesses 120 consecutively arranged along the first direction 105.

Referring to the cross-sectional view of FIG. 3B taken along the first direction 105 and denoted by the intersection line A-A′ in FIG. 3A, conductive plugs 121 remain after etching the recesses 120 into the conductive structure 118. Due to the tapered etch process, the recesses 120 comprise opposing side walls along the first direction 105 that are tapered from a top side 122 to a bottom side 123. Contrary thereto, the conductive plugs 121 comprise opposing sidewalls along the first direction 105 that are tapered from the bottom side 123 to the top side 122. Hence, a dimension of the conductive plugs 121 along the first direction 105 is larger at the bottom side 123 than at the top side 122.

Referring to the cross-sectional view of FIG. 3C which is taken along the second direction 106 and denoted by the intersection line B-B′ in FIG. 3A, the etch mask structure 119 covers the top side 122 of the conductive plugs 121.

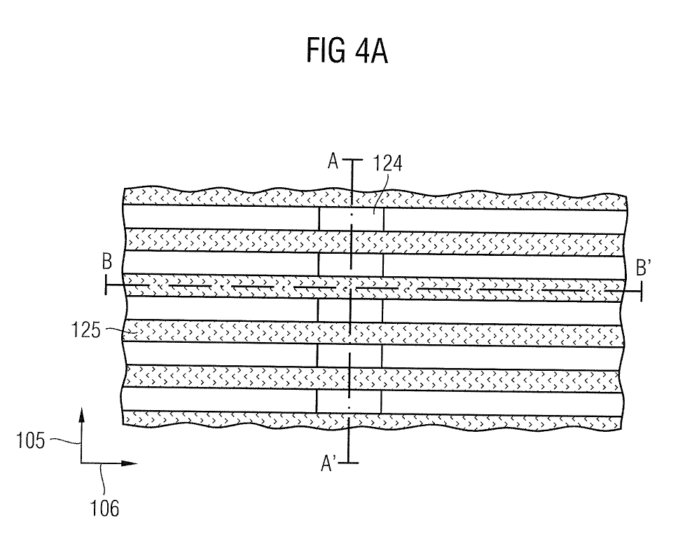

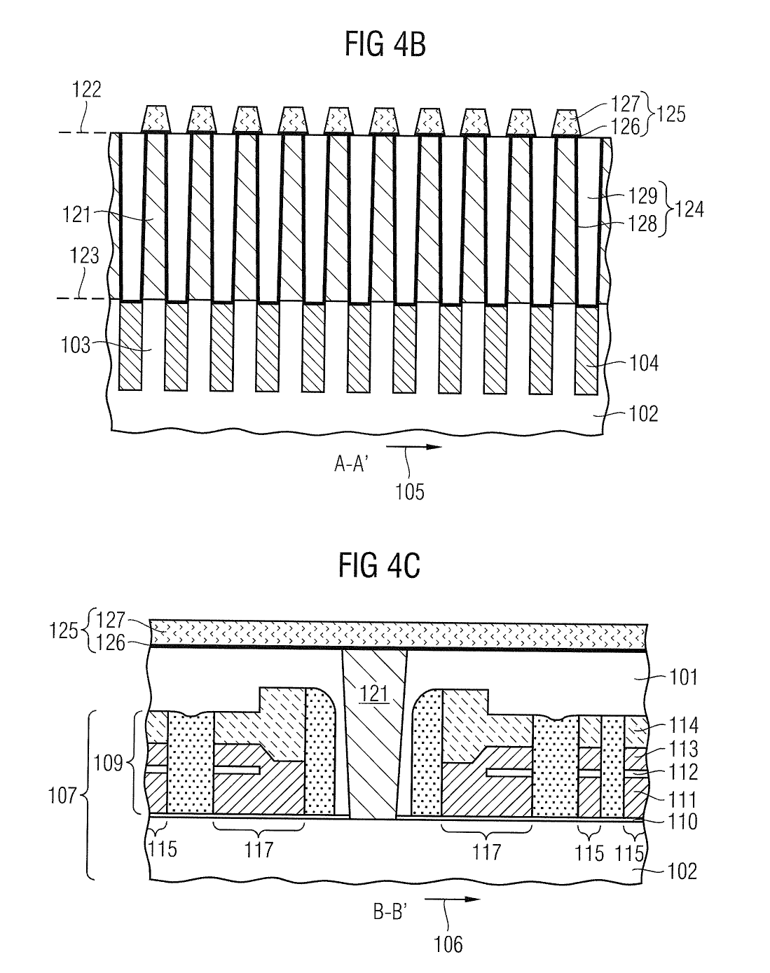

FIG. 4A is a schematic top view during manufacture of the interconnection structure following the process stage illustrated in FIG. 3A. After filling the recesses 120 (not shown in FIG. 4A, see FIG. 3A) with a dielectric structure 124, conductive lines 125 extending along the second direction 106 are provided on top of the conductive plugs 121 and the insulating layer 101. Each of the conductive lines 125 is arranged in contact with one of the conductive plugs 121. The conductive lines 125 may be provided by deposition of a liner layer and a metal layer thereon, followed by patterning the liner layer and that metal layer to shape of the conductive lines 125.

Referring to the schematic cross-sectional view of FIG. 4B which is taken along the first direction 105 and denoted by A-A′ in FIG. 4A, the conductive lines 125 formed on top of the conductive plugs 121 comprise the liner layer 126 and the metal layer 127 thereon. The dielectric structure 124 filling the recesses 120 between neighboring contact plugs 121 comprises a pre-metal dielectric liner 128 and a pre-metal dielectric 129. The pre-metal dielectric 129 may be formed as BPSG (boron-doped phosphor silicate glass), as a HARP (high aspect ratio process)-dielectric, as SOD (spin-on dielectric) or as any further oxide. A cross-sectional view of the interconnection structure comprising the conductive lines 125 and the conductive plugs 121 along an intersection line as denoted by B-B′ in FIG. 4A is shown in FIG. 4C.

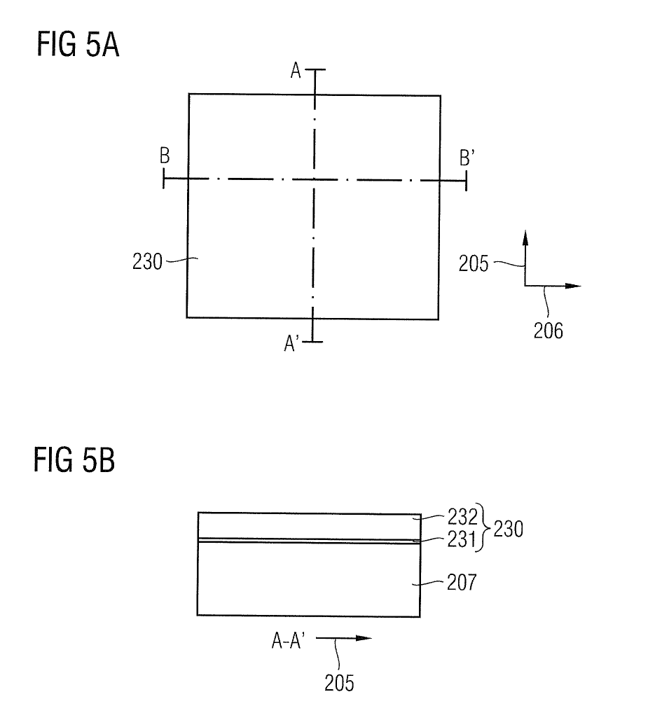

A further embodiment of a method of manufacturing an interconnection structure is illustrated in FIGS. 5A to 7C.

Referring to the schematic top view shown in FIG. 5A, a conductive structure 230 is provided on a carrier 207 (carrier 207 not visible in top view of FIG. 5A). A cross-sectional view of the conductive structure 230 formed on the carrier 207 is shown in FIG. 5B along an intersection line denoted by A-A′ in FIG. 5A. The intersection line A-A′ extends along a first direction 205 perpendicular to a second direction 206. The conductive structure 230 comprises a liner 231 and a conductive layer 232 formed thereon. As an example, the liner may be of Ti/TiN and the conductive layer may be of W.

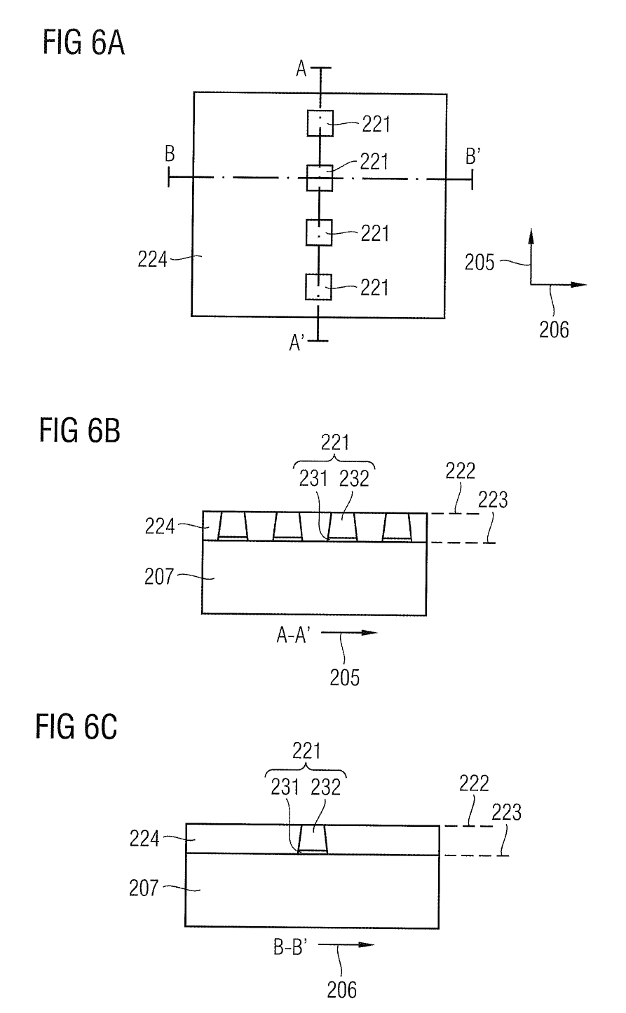

Referring to the schematic top view illustrated in FIG. 6A, the conductive structure 230 of FIG. 5A is patterned to form conductive plugs 221. The patterning of the conductive structure 230 may be carried out by forming an etch mask structure thereon followed by removing those parts of the conductive structure 230 which are not covered by the etch mask structure. Then, a dielectric material 224 is provided to replace the removed parts of the conductive structure 230 and to electrically isolate the conductive plugs 221 from each other.

As can be gathered from the schematic cross-sectional view of FIG. 6B which is taken along the first direction 205 and denoted by the intersection line A-A′ in FIG. 6A, the conductive plugs 221 comprising material of the liner 231 and the conductive layer 232 are delimited by sidewalls opposed along the first direction 205. These sidewalls are tapered from a bottom side 223 to the top side 222. The sidewall profile of the conductive plugs 221 is caused by a tapered etch of the conductive structure 230.

FIG. 6C shows a schematic cross-sectional view taken along the second direction 206 and denoted by the intersection line B-B′ in FIG. 6A. As the sidewall profile of the conductive plugs 221 is determined by the taper of the etch process affecting the conductive structure 230, opposing sidewalls delimiting the conductive plugs 221 along the second direction 206 are also tapered from the bottom side 223 to the top side 222. Hence, the dimensions of the conductive plugs 221 along the first and second directions 205, 206 are larger at the bottom side 223 than at the top side 222, respectively.

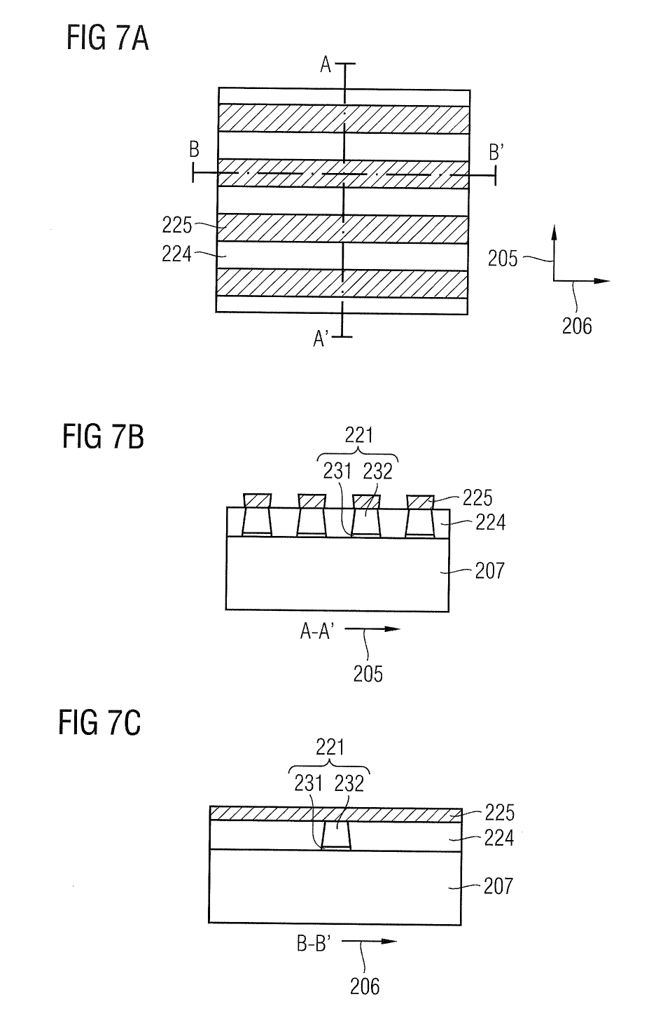

Referring to the schematic top view shown in FIG. 7A, conductive lines 225 running in parallel along the second direction 206 are provided on the dielectric material 224 and the conductive plugs 221, wherein each of the conductive lines 225 is arranged in contact with one of the conductive plugs 221.

FIGS. 7B and 7C furthermore illustrate schematic cross-sectional views taken along the first and second directions 205, 206 and denoted by the intersection lines A-A′ and B-B′ in FIG. 7A. These figures illustrate the interconnection structure comprising the conductive plugs 221 and the conductive lines 225.

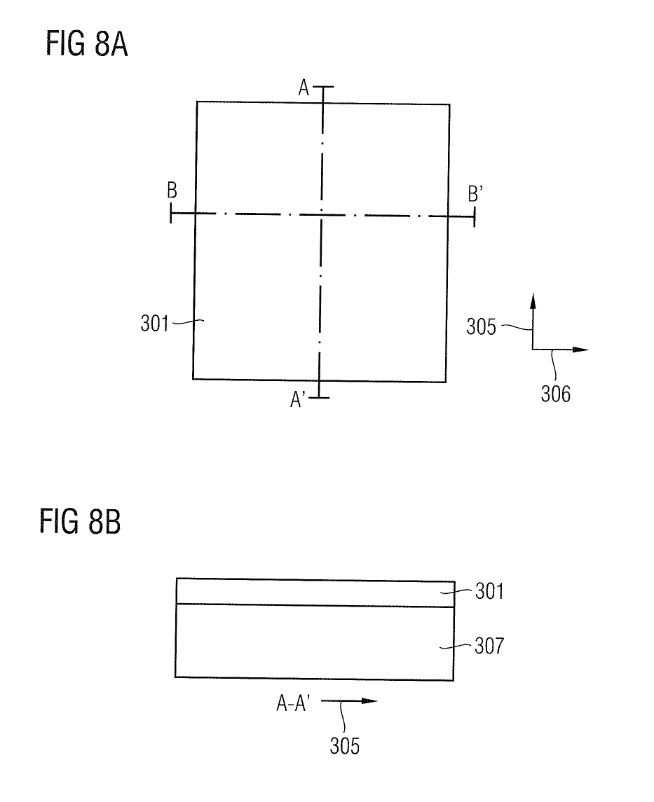

A further embodiment related to yet another method of manufacturing an interconnection structure will now be explained with reference to schematic top views and cross-sectional views illustrated in FIGS. 8A to 12C.

Referring to the schematic top view of FIG. 8A, an insulating layer 301 is provided on a carrier 307 (not visible in top view).

The insulating layer 301 formed on the carrier 307 is further illustrated in the cross-sectional view of FIG. 8B which is taken along the first direction 305 and denoted by the intersection line A-A′ in FIG. 8A.

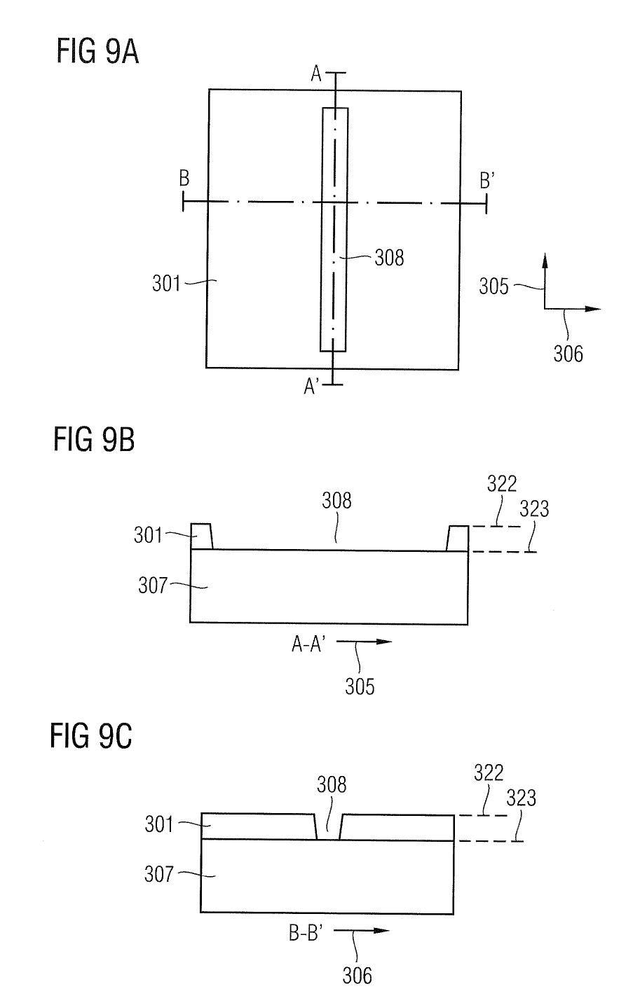

Referring to the schematic top view of FIG. 9A, a linear opening 308 extending along the first direction 305 is etched into the insulating layer 301.

As can be gathered from FIG. 9B showing a cross-sectional view along the first direction 305 denoted by A-A′ in FIG. 9A, opposing sidewalls delimiting the linear opening 308 along the first direction 305 comprise a taper from a top side 322 to a bottom side 323 caused by a tapered etch process.

Referring to the cross-sectional view of FIG. 9C which is taken along the second direction 306 and denoted by B-B′ in FIG. 9A, opposing sidewalls delimiting the linear opening 308 along the second direction 306 are tapered from the top side 322 to the bottom side 323 for the reason set out above.

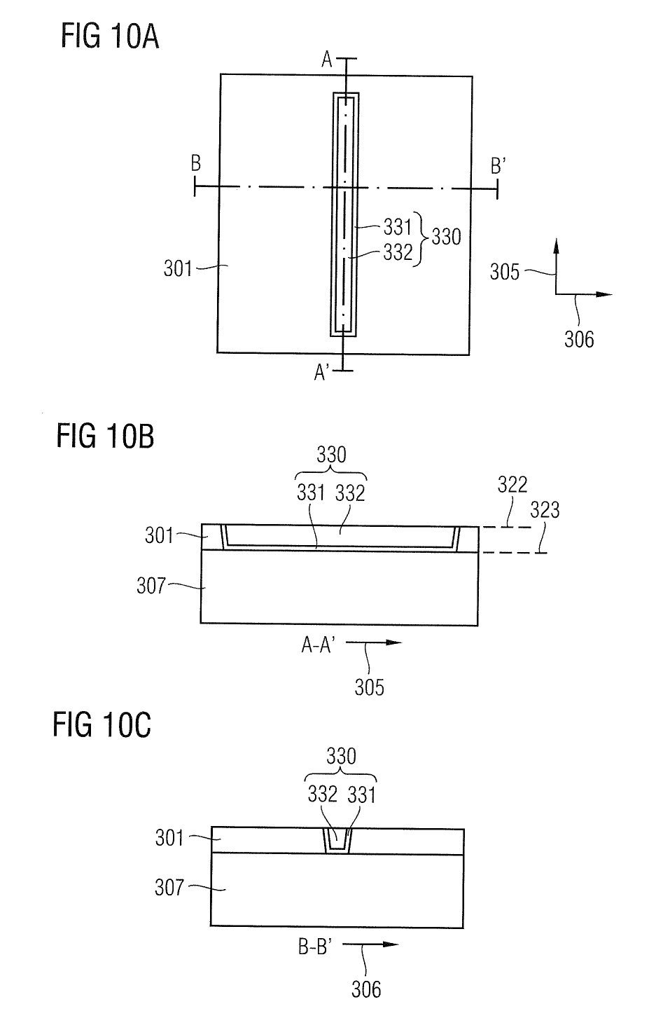

Referring to the schematic top view of FIG. 10A, the linear opening 308 is filled with a conductive structure 330 comprising a liner 331 covering a bottom side and sidewalls of the linear opening 308 and a conductive layer 332 filling remaining portions of the linear opening 308. When forming the conductive structure 330, the liner 331 and the conductive layer 332 may first be deposited in such a way that the insulating layer 301 is also covered. Thereafter, these layers may again be removed from a top side of the insulating layer 301, e.g. by chemical-mechanical polishing, leaving the conductive structure 330 within the linear opening 308.

Referring to FIGS. 10B and 10C showing schematic cross-sectional views along the first and second directions 305, 306 denoted by the intersection lines A-A′ and B-B′ in FIG. 10A, the liner 331, at the present stage of manufacture, covers not only the bottom side 323 adjoining a top side of the carrier 307, but also opposing sidewalls delimiting the conductive structure 330 along the first and the second directions 305, 306, respectively.

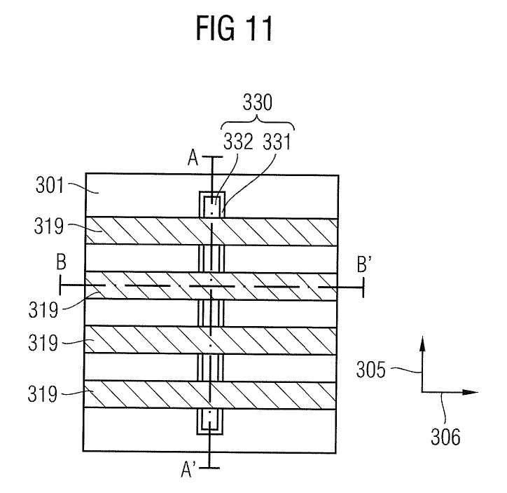

Referring to the schematic top view shown in FIG. 11, an etch mask structure 319 comprising equally spaced parallel lines running along the second direction 306 is provided on the insulating layer 301 and the conductive structure 330. The etch mask structure 319 covers the conductive structure 330 in those regions where conductive plugs are to be formed.

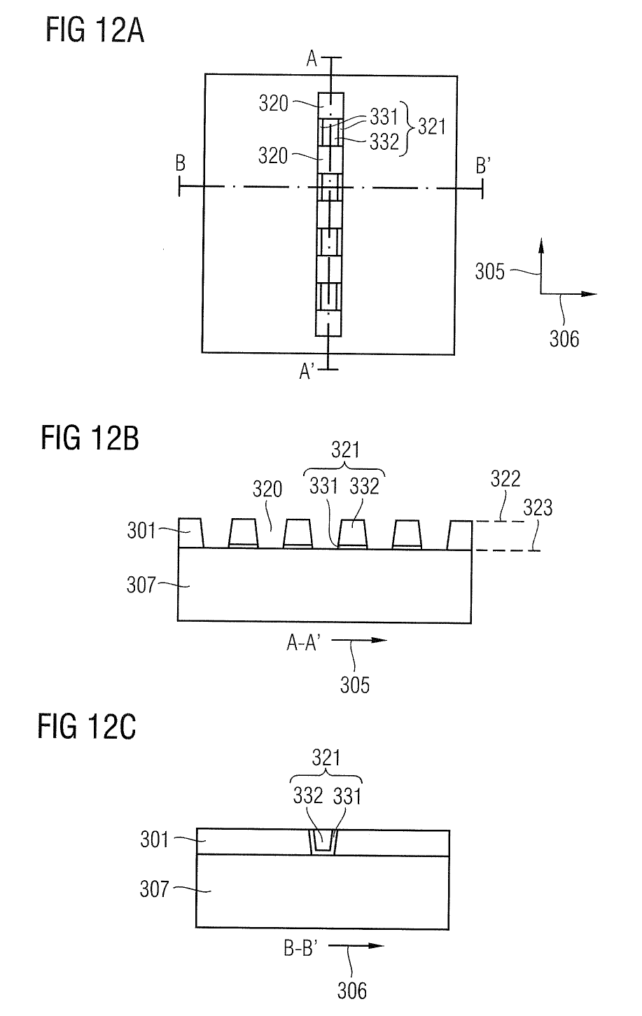

As can be gathered from the schematic top view shown in FIG. 12A, recesses 320 are etched into those parts of the conductive structure 330, which are not covered by the etch mask structure 319. As a result, the conductive structure 330 is patterned into conductive plugs 321 consecutively arranged along the first direction 305.

Referring to the schematic cross-sectional view along the first direction 305 denoted by the intersection line A-A′ in FIG. 12A, patterning of the conductive structure 330 by means of the etch mask structure 319 determines a profile of the sidewalls delimiting the contact plugs 321 along the first direction 305. Due to a tapered etch process of the conductive structure 330 from the top side 322 to the bottom side 323, the contact plugs 321 are contrarily tapered from the bottom side 323 to the top side 322. Furthermore, there is no liner covering those sidewalls, which delimit the contact plugs 321 along the first direction 305.

As the patterning of the conductive structure 330 by means of the etch mask structure 319 does not affect the profile of sidewalls of the contact plugs 321 opposed along the second direction 306, the liner 331 still covers those sidewalls. Furthermore, when comparing opposing sidewalls of the contact plugs 321 along the first and second directions 305, 306, it is to be noted that a taper of the sidewalls opposed along the first direction is not only opposite to a taper of sidewalls opposed along the second direction 306, but there is a further structural difference in that the conductive liner 331 merely covers sidewalls delimiting the contact plugs 321 along the second direction 306 whereas the liner 331 is absent at sidewalls delimiting the contact plugs 321 along the first direction 305. It is to be further noted that a taper angle of sidewalls opposed along the first direction 305 may differ from the taper angle of sidewalls opposed along the second direction 306.

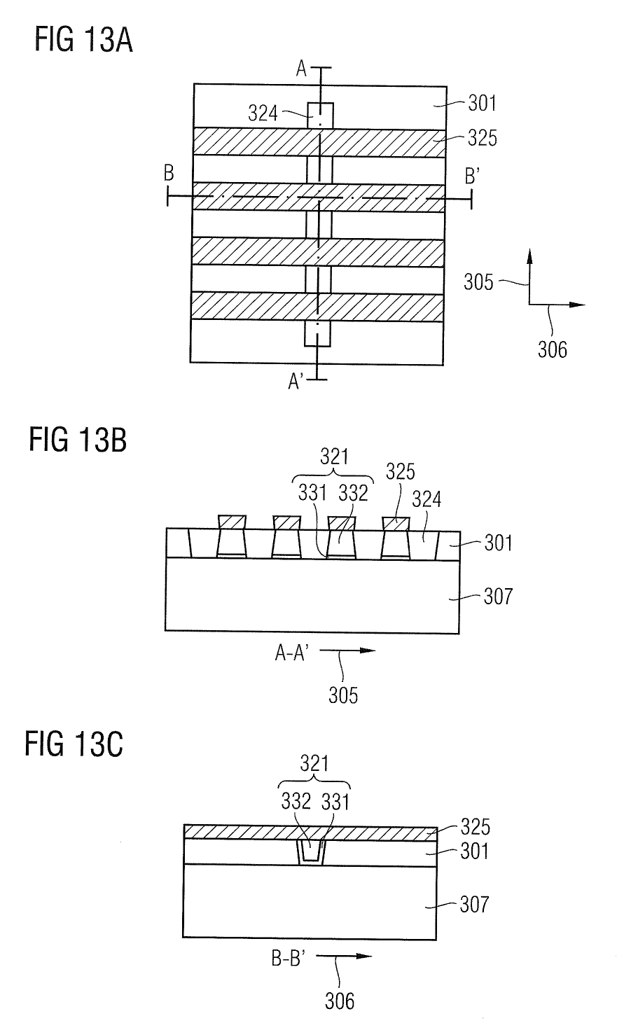

Referring to the schematic top view shown in FIG. 13A, conductive lines 325 running in parallel along the second direction 306 are provided on the insulating layer 301 and the conductive plugs 321, wherein each of the conductive lines 325 is arranged in contact with one of the conductive plugs 321. The recesses 320 are filled with a dielectric structure 324.

FIGS. 13B and 13C furthermore illustrate schematic cross-sectional views taken along the first and second directions 305, 306 denoted by the intersection lines A-A′ and B-B′ in FIG. 13A and illustrate the interconnection structure comprising the conductive plugs 321 and the conductive lines 325.

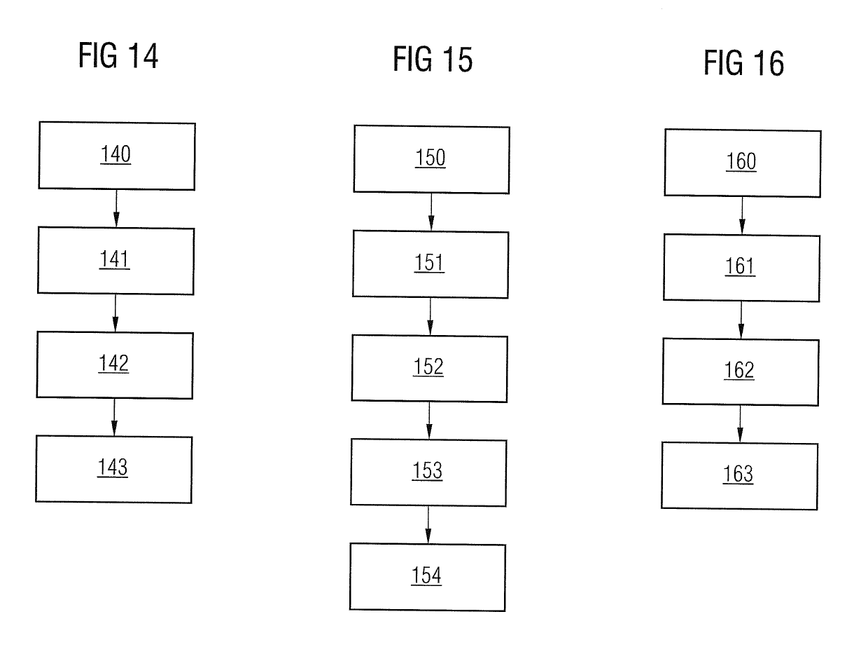

In the following, embodiments of a method of manufacturing an interconnection structure will be briefly explained with reference to flow charts illustrated in FIGS. 14 to 16. As is shown in FIG. 14, for manufacturing an interconnection structure, first, a layer structure is provided on a carrier, the layer structure comprising at least a conductive portion (140). Then, recesses are etched into the conductive portion to segment the conductive portion into a plurality of conductive regions arranged along a first direction (141). Thereafter, the recesses are filled with a dielectric material (142). Then, conductive lines, wherein each of the conductive lines is arranged in contact with at least one of the conductive regions and extends along a second direction intersecting the first direction (143).

Turning now to FIG. 15, a further embodiment of a method of manufacturing an interconnection structure will be briefly explained. First, a linear opening is etched into an insulating layer formed on a carrier, the linear opening extending along first direction (150). Then, the linear opening is filled with a conductive structure (151). Thereafter, recesses are etched into the conductive structure to segment the conductive structure into a plurality of conductive regions arranged along the first direction (152). Then, the recesses are filled with a dielectric material (153). Thereafter, conductive lines are provided on the insulating layer and the conductive regions, wherein each of the conductive lines is arranged in contact with one of the conductive regions and extends along a second direction intersecting the first direction (154).

Turning now to FIG. 16, yet another embodiment of a method forming an interconnection structure will be briefly explained. First, a conductive structure is provided on a carrier (160). Then, recesses are etched into the conductive structure to segment the conductive structure into a plurality of conductive regions arranged along a first direction (161). The recesses are then filled with a dielectric material (162). Thereafter, conductive lines are provided on the conductive regions and the dielectric material, wherein each of the conductive lines is arranged in contact with at least one of the conductive regions and extends along a second direction intersecting the first direction (163).

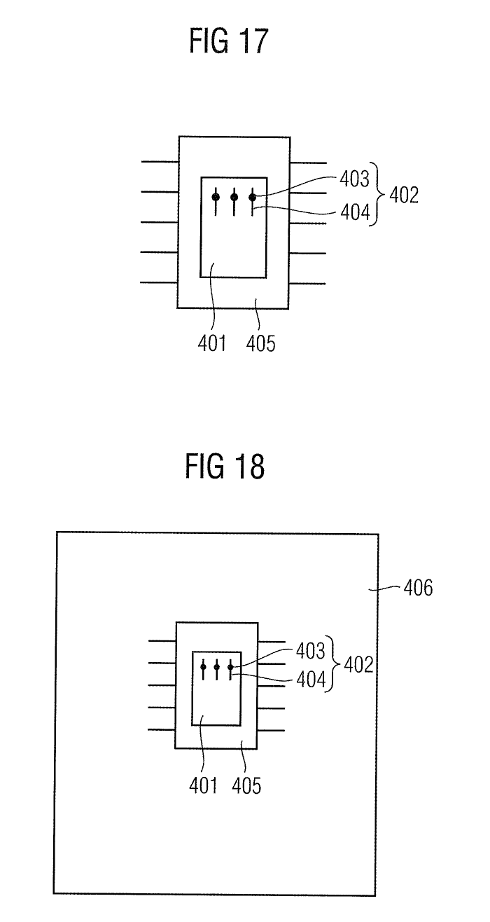

FIG. 17 is a simplified schematic illustration of an integrated circuit 401. The integrated circuit 401 may be a volatile or non-volatile memory circuit, such as a flash memory, DRAM (Dynamic Random Access Memory), ROM (Read Only Memory) or any other type of memory device, for example an MRAM, PCRAM or FeRAM or it may also serve for high frequency or power applications. The integrated circuit 401 includes an interconnection structure 402 comprising contact plugs 403 and conductive lines 404 extending along a second direction intersecting the first direction, wherein a top side of each of the contact plugs 403 is in contact with one of the conductive lines 404. Opposing sidewalls delimiting the contact plugs along the first direction are tapered from a bottom side to the top side. As an example, the contact plugs may be formed of a doped semiconductor material. Furthermore, the contact plugs may comprise a liner being at least present at a bottom side. The liner may be absent at sidewalls thereof. As a further example, the liner may be covering opposing sidewalls delimiting the contact plugs along the second direction but absent on opposing sidewalls delimiting the contact plugs along the first direction. The integrated circuit 401 may be placed in a semiconductor package 405.

According to a further embodiment, an electronic system 406 is provided that comprises an integrated circuit 401 as explained above. The electronic system 406 may be an audio system, a video system, a computer system, a game console, a communication system, a cell phone, a data storage system, a data storage module, a graphic card or portable storage device comprising an interface to a computer system, an audio system, a video system, a game console or data storage system.

Having described exemplary embodiments of the invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. A method of manufacturing an interconnection structure, comprising:
forming a structure on a carrier, the structure comprising at least a conductive portion;
etching recesses into the conductive portion to segment the conductive portion into a plurality of conductive regions arranged along a first direction;
filling the recesses with a dielectric material; and
forming conductive lines above the conductive regions, wherein individual conductive lines are electrically coupled to at least one of the conductive regions and extend along a second direction intersecting the first direction.

2. The method of claim 1, wherein the structure is formed to include an insulating portion.

3. The method of claim 2, wherein the structure is formed by etching an opening into an insulating layer and filling the opening with a conductive material to provide the conductive portion laterally adjacent to a remaining portion of the insulating layer, which constitutes the insulating portion.

4. The method of claim 3, wherein the opening and the recesses are formed by tapered etch processes such that a dimension of a bottom side of the conductive regions is larger along the first direction and smaller along the second direction than the corresponding dimension of the top side of the conductive regions.

5. The method of claim 1, wherein the recesses are formed by a tapered etch process such that the dimensions of the conductive regions along the first and second directions are larger at a bottom side than at the top side.

6. The method of claim 1, wherein the conductive portion is formed from a liner layer and a metal layer disposed on the liner layer.

7. The method of claim 1, wherein the conductive portion is formed from a doped semiconductor layer.

8. The method of claim 1, wherein a bottom side of each of the conductive regions is formed to adjoin a top side of a conductive zone.

9. The method of claim 8, wherein the conductive zone is formed as a semiconductor zone of an active area of a semiconductor device.

10. The method of claim 1, wherein the conductive regions are shaped as contact plugs.

11. A method of manufacturing an integrated circuit, comprising:
etching a linear opening into an insulating layer formed on a carrier, the linear opening extending along a first direction;
filling the linear opening with a conductive structure;
etching recesses into the conductive structure to segment the conductive structure into a plurality of conductive regions arranged along the first direction;
filling the recesses with a dielectric material; and
forming conductive lines above the insulating layer and the conductive regions, wherein individual conductive lines are electrically coupled to one of the conductive regions and extend along a second direction intersecting the first direction.

12. The method of claim 11, wherein the linear opening and recesses are formed by tapered etch processes such that a dimension of a bottom side of the conductive regions is larger along the first direction and smaller along the second direction than the corresponding dimensions of the top side of the conductive regions.

13. The method of claim 11, wherein, prior to etching the recesses into the conductive structure, an etch mask structure comprising parallel lines is formed on the insulating layer and the conductive structure, wherein the parallel lines are equally spaced along the first direction and extend along the second direction.

14. The method of claim 11, wherein the conductive structure are formed to include a liner layer and a metal layer formed thereon.

15. The method of claim 11, wherein the conductive structure is formed to include a doped semiconductor layer.

16. The method of claim 11, wherein a pitch between two neighboring conductive lines equals about 2×F, where F corresponds to a minimum lithographic feature size.

17. The method of claim 11, wherein a bottom side of the linear opening is formed to at least partly adjoin a top side of a conductive zone.

18. The method of claim 17, wherein the conductive zone is formed as a semiconductor zone of an active area of a semiconductor device.

19. The method of claim 11, wherein the conductive regions are shaped as contact plugs.

20. A method of manufacturing an integrated circuit, comprising:
forming a conductive structure on a carrier;
etching recesses into the conductive structure to segment the conductive structure into a plurality of conductive regions arranged along a first direction;
filling the recesses with a dielectric material; and
forming conductive lines above the conductive regions and the dielectric material, wherein individual conductive lines are electrically coupled to at least one of the conductive regions and extend along a second direction intersecting the first direction.

21. The method of claim 20, wherein the conductive regions are shaped as contact plugs.

22. The method of claim 20, wherein the conductive structure is formed to include a liner layer and a metal layer formed on the liner layer.

23. The method of claim 20, wherein the conductive layer is formed to include a doped semiconductor layer.

24. The method of claim 20, wherein the recesses are formed by a tapered etch process such that the dimensions of the conductive regions along the first and second directions are larger at a bottom side than at the top side.

25. The method of claim 20, wherein a bottom side of the conductive regions is formed to adjoin a top side of a conductive zone.

26. The method of claim 20, wherein the conductive zone is formed as a semiconductor zone of an active area of a semiconductor device.

27. An integrated circuit, comprising:
contact plugs comprising a doped semiconductor material arranged along a first direction; and
conductive lines extending along a second direction intersecting the first direction, wherein a top side of each of the contact plugs is in contact with one of the conductive lines and opposing sidewalls delimiting the contact plugs along the first direction are tapered from a bottom side to the top side.

28. The integrated circuit of claim 27, wherein a bottom side of each of the contact plugs is in contact with a top side of a conductive zone.

29. The integrated circuit of claim 27, wherein opposing sidewalls delimiting the contact plugs along the second direction are tapered from the top side to the bottom side.

30. An electronic system comprising the integrated circuit of claim 27.

31. The electronic system of claim 30, wherein the electronic system is selected from the group consisting of: an audio system, a video system, a computer system, a game console, a communication system, a cell phone, a data storage system, a data storage module, a graphic card or portable storage device comprising an interface to a computer system, an audio system, a video system, a game console, and a data storage system.

32. An integrated circuit, comprising:
a plurality of contact plugs arranged along a first direction;
conductive lines extending along a second direction intersecting the first direction, wherein:
a top side of each of the contact plugs is in contact with one of the conductive lines;
opposing sidewalls delimiting the contact plugs along the first direction are tapered from the bottom side to the top side; and
the contact plugs further comprise a liner disposed at the bottom side and at opposing sidewalls delimiting the contact plugs along the second direction but absent at opposing sidewalls delimiting the contact plugs along the first direction.

33. The integrated circuit of claim 32, wherein a bottom side of each of the contact plugs is in contact with a top side of a conductive zone.

34. An integrated circuit, comprising:
contact plugs comprising a liner disposed along a bottom side but absent at sidewalls of the contact plugs, the contact plugs being arranged along a first direction; and
conductive lines extending along a second direction intersecting the first direction, wherein a top side of each of the contact plugs is in contact with one of the conductive lines and opposing sidewalls delimiting the contact plugs along the first direction are tapered from a bottom side to the top side.

35. The integrated circuit of claim 34, wherein a bottom side of each of the contact plugs is in contact with a top side of a conductive zone.
